(19) United States
(12) Patent Application Publication
(10) Pub. No.: US 2017/0186667 A1
(43) Pub. Date: Jun. 29, 2017

(54) COOLING OF ELECTRONICS USING FOLDED FOIL MICROCHANNELS

(71) Applicant: Intel Corporation, Santa Clara, CA (US)

(72) Inventors: Arnab Choudhury, Chandler, AZ (US); Patrick Nardi, Scottsdale, AZ (US); William Nicholas Labanok, Gilbert, AZ (US); Kelly P. Lofgreen, Phoenix, AZ (US)

(21) Appl. No.: 14/757,997

(22) Filed: Dec. 26, 2015

(51) Int. Cl. H01L 23/473; H01L 23/00; H01L 21/48; H01L 23/053; G06F 1/20; H01L 23/367

(52) U.S. Cl. CPC H01L 23/473; G06F 1/20; H01L 23/3672; H01L 23/3675; H01L 21/4878; H01L 21/4882; H01L 23/053; H01L 24/32; H01L 2224/32245

(57) ABSTRACT

Embodiments are generally directed to cooling of electronics using folded foil microchannels. An embodiment of an apparatus includes a semiconductor die; a substrate, the semiconductor die being coupled with the substrate; and a cooling apparatus for the semiconductor die, wherein the cooling apparatus includes a folded foil preform, the folded foil forming a plurality of microchannels, and a fluid coolant system to direct a fluid coolant through the microchannels of the folded foil.

### TECHNICAL FIELD

Embodiments described herein generally relate to the field of electronic devices and, more particularly, to cooling of electronics using folded foil microchannels.

### BACKGROUND

Electronic devices such as microprocessors, and in particular high power server products, are demonstrating trends that require improved heat removal from silicon structures:

Density factor is decreasing trend due to the increasing number of processor cores and inclusion of new technologies;

Total thermal design power (TDP) is increasing, thus demanding that the cross plane heat removal be improved which is pushing the capabilities of air cooling; and

Emergence of multichip package (MCP) technology in, for example, high power server use with on-package memory generates increasing amounts of heat in an electronic device. Further, coating with certain polymeric layers may present thermal resistance that is too high for traditional air cooling.

However, existing liquid cooling technology is generally inadequate to address such heating concerns because of factors including costs, risks to electronic devices, and lack of sufficient cooling capacity.

### BRIEF DESCRIPTION OF THE DRAWINGS

Embodiments described here are illustrated by way of example, and not by way of limitation, in the figures of the accompanying drawings in which like reference numerals refer to similar elements.

FIG. 1 is an illustration of an apparatus with fluid cooling via folded foil microchannels;

FIGS. 2A to 2C illustrate cooling apparatuses in a device or system according to an embodiment;

FIG. 3 illustrates a conventional process for skiving of channels for liquid cooling;

FIGS. 4A to 4D illustrate fabrication of a device utilizing folded foil according to an embodiment;

FIGS. 5A and 5B illustrate the formation of folded foil material according to an embodiment;

FIG. 6A to 6D illustrate fabrication of a fluid cooling solution on a die according to an embodiment;

FIGS. 7A and 7B further illustrate elements of a fluid cooling solution for a die according to an embodiment;

FIG. 8A to 8D illustrate fabrication of a fluid cooling solution in an integrated coldplate according to an embodiment;

FIGS. 9A to 9D illustrate coolant flows through folded foil microchannels in an integrated coldplate according to an embodiment;

FIG. 10 is a flow chart to illustrate fabrication of a package including folded foil microchannels according to an embodiment;

FIG. 11 is an illustration of components of a computing system including a component utilizing fluid cooling through use of folded foil material; and

FIG. 12 is an illustration of integrated coldplate and enabled coldplate solutions according to an embodiment.

### DETAILED DESCRIPTION

Embodiments described herein are generally directed to cooling of electronics using folded foil microchannels.

As used herein, the following terms apply:

“Computing device” or “computing system” refers to a computer, including, but limited a server, or other electronic device that includes processing ability.

“Electronic device” refers to any apparatus, device, or system having an electronic system to provide one or more functions, the functions including, but not limited to, mobile devices and wearable devices.

In some embodiments, fluid cooling is provided for electronic devices using folded foil. In some embodiments, microchannels (MCs) for fluid flow are formed using folding of a metal foil, allowing for economical and efficient cooling using fluid coolant flow through the microchannels. As used here, a fluid refers to a substance without fixed shape that is capable of flowing, including a liquid or gas.

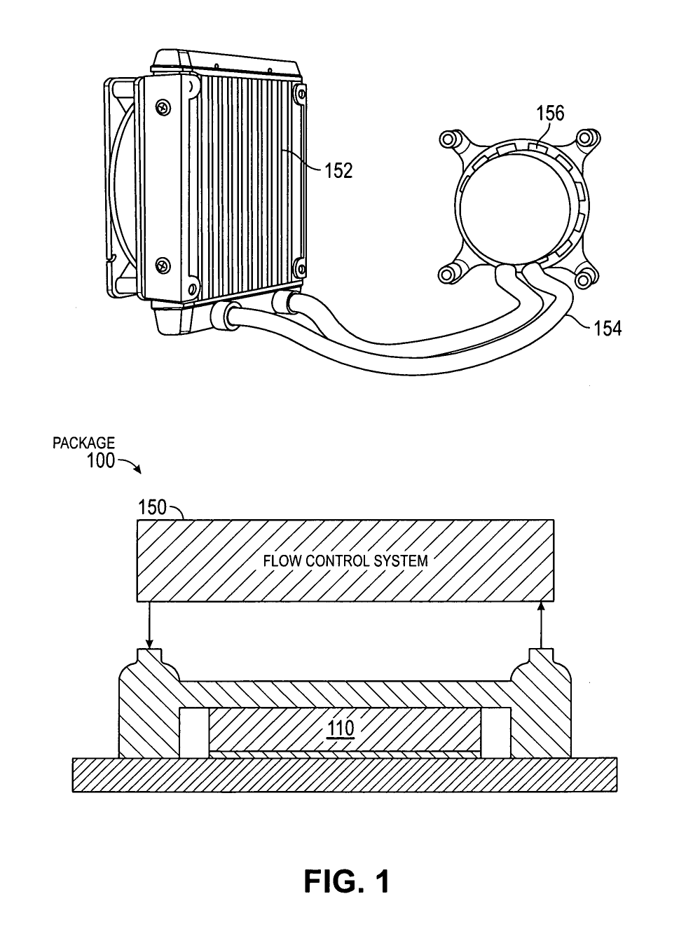

FIG. 1 is an illustration of an apparatus with fluid cooling via folded foil microchannels. In some embodiments, an apparatus includes a semiconductor die 110 coupled with a substrate 115, the apparatus further including a cooling solution using fluid flow, including a flow control system 150 to direct coolant through, for example, a flow manifold coupled with a coldplate body.

In some embodiments, the coolant is directed (or pumped) through microchannels formed using folded foil to draw heat away from the die 110. In one example, the flow control system may include a pump unit 152 to pump fluid through hoses 154 into a manifold unit 156. However, embodiments are not limited to a particular flow control system for fluid cooling, but rather utilize any known technology for pumping or otherwise directing a fluid coolant through microchannels to cool a die.

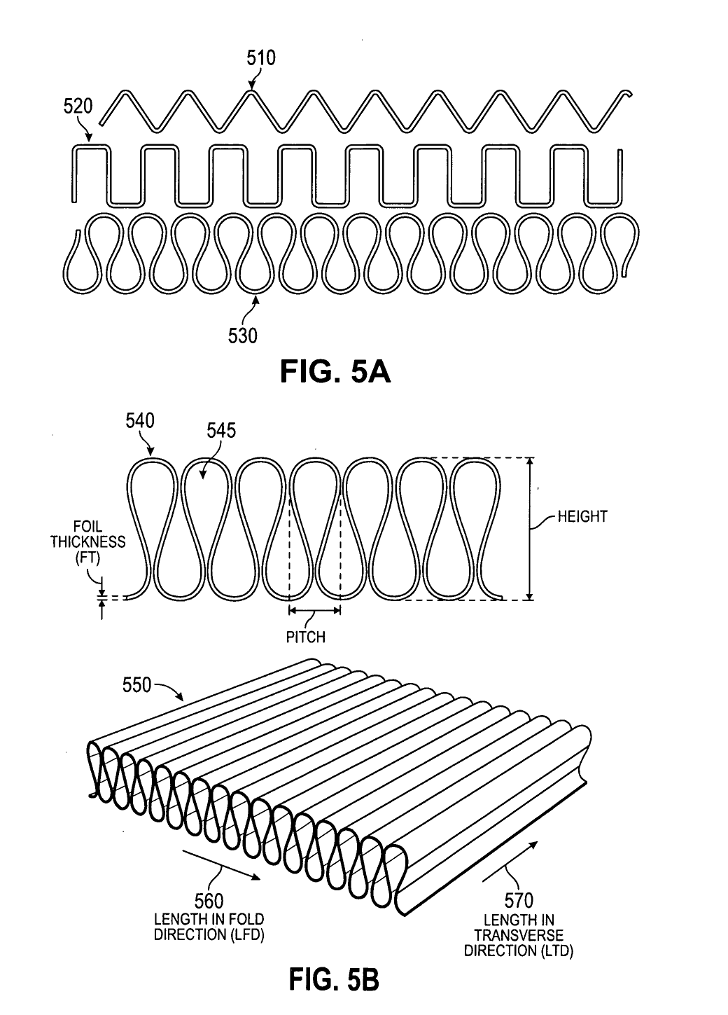

In some embodiments, a folded foil material for a cooling solution may be generated as illustrated and described in FIGS. 5A and 5B.

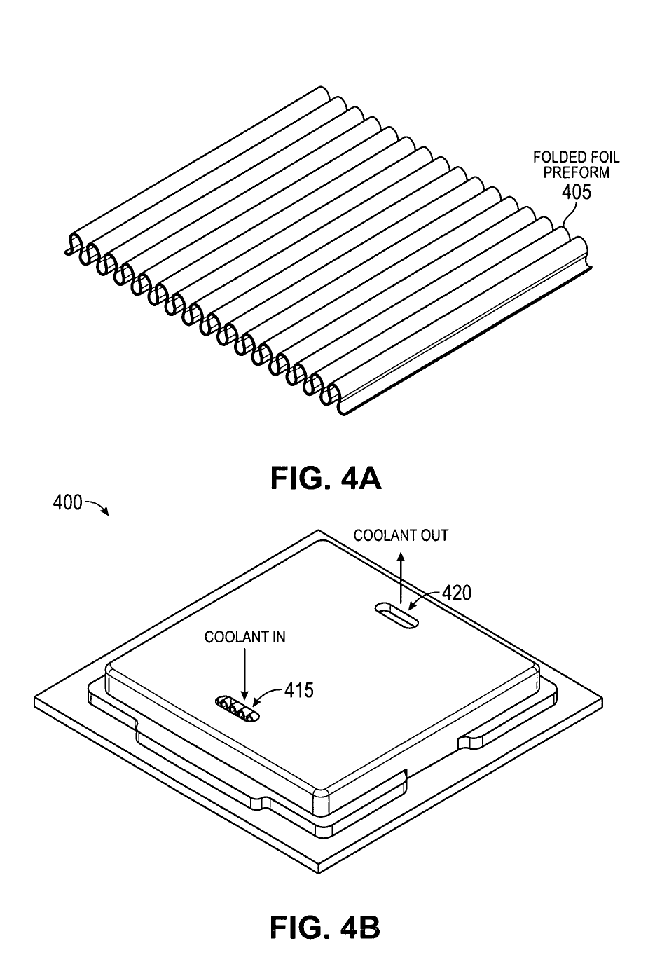

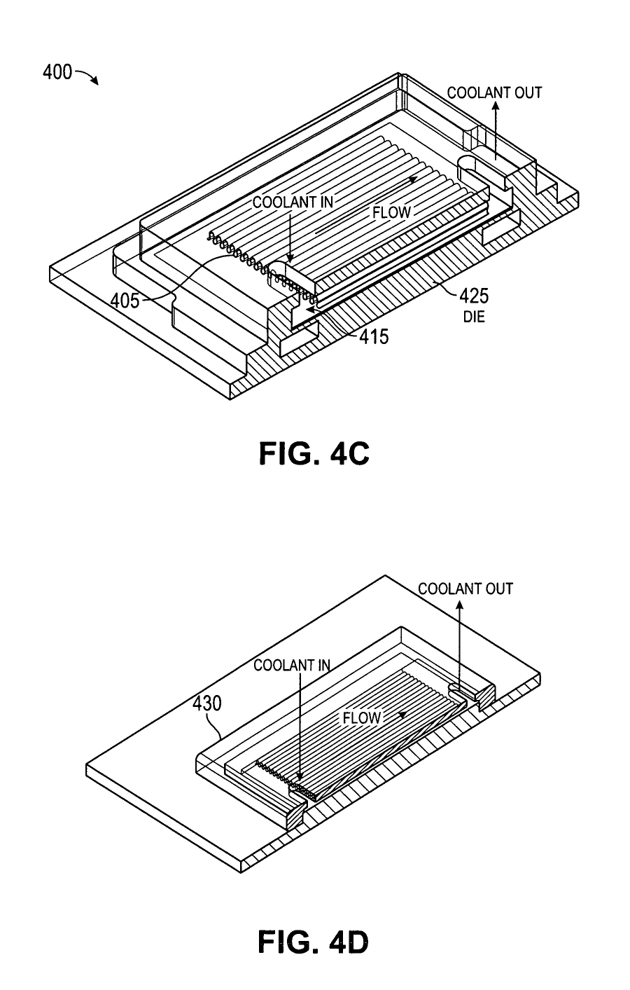

In some embodiments, a cooling apparatus to utilize folded foil may be fabricated as illustrated and described in FIGS. 4A to 4D and FIGS. 6A to 9D.

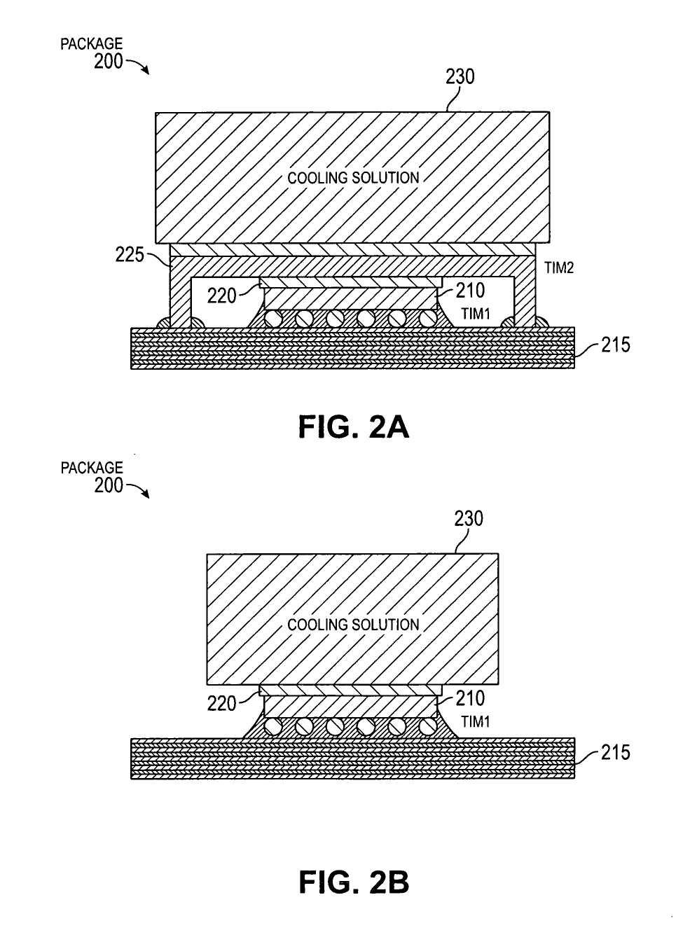

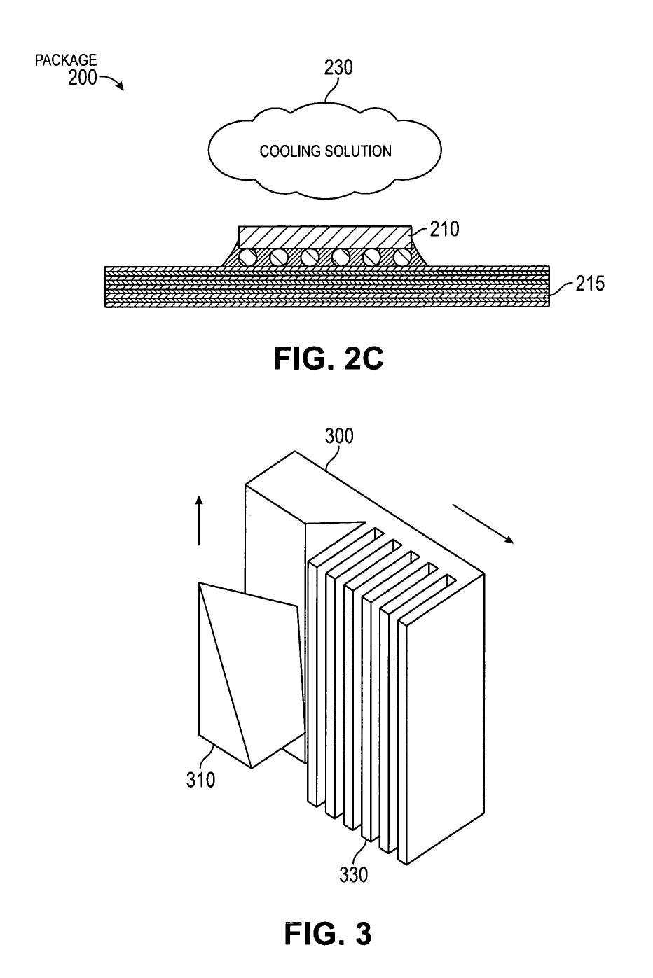

FIGS. 2A to 2C illustrate cooling apparatuses utilized in a device or system according to an embodiment. In some embodiments, the apparatuses may be utilized in an embodiment of a fluid cooling system with folded foils.

FIG. 2A: Certain products utilize integrated heat spreaders (IHS) as lids over the semiconductor dies (such as silicon dies). FIG. 2A illustrates a “2-TIM” structure for the cooling of a die 210 coupled to a substrate or other material 215 in a particular package 200. As illustrated in FIG. 2A, a heat plane 220 with a first thermal interface material (TIM1) is coupled with the die 210, over which an integrated heat spreader 225 with a second thermal interface material (TIM2) is provided. Thermal solutions 230, such as passive heat sinks, heat sink/fan combinations, or fluid cooling solutions, may be implemented on the integrated heat spreader 225.

FIG. 2B: FIG. 2B illustrates a “1-TIM” structure for the cooling of the die 210 on the substrate 215. The illustrated cooling structure includes a heat plane 220 with a first thermal material (TIM1), in which the cooling solution 230 is implemented on the heat plane 220. In contrast with the 2-TIM structure, the 1-TIM provides a cooling structure that does not include an integrated heat spreader).

FIG. 2C: FIG. 2C illustrates a 0-TIM structure for the cooling of the die 210 on the substrate 215, in which the cooling solution 230 is implemented directly on the die (such as in an air cooled structure).

The 2-TIM configuration, as illustrated in FIG. 2A, provides additional cooling capacity through use of the integrated heat spreader. However, limitations of this configuration include a large stackup height, and multiple thermal interfaces where thermal interface materials must be applied. With thermal performance of common thermal interface materials being highly optimized to essentially a physical limit, a fundamental revision in the thermal stackup (such as elimination of a TIM layer by design) is required to improve to the thermal management of high power microprocessors.

In some embodiments, an alternative cooling solution utilizes fluid cooling. Conventional processes for the generation of materials for fluid cooling are generally expensive and difficult. For example, to generate channels in a metal, a convention process involves the cutting (skiving) of channels.

FIG. 3 illustrates a conventional process for skiving of channels for liquid cooling. In this process, a material 300 such as copper is to be machined to generate microchannels 330 for cooling using a fluid cooling. The microchannels 330 are commonly generated by use of a skiving tool 310 to cut the necessary channels. However, skiving is an expensive and difficult process, which increases the overall cost of a cooling solution.

In some embodiments, a fluid cooling solution utilizes folded foil microchannels in a fluid cooling solution. In some embodiments, the formation of folded foil microchannels provides an efficient and effective alternative to silicon microchannels and skived microchannels. The generation of folded foil microchannels is illustrated in FIGS. 5A and 5B. In some embodiments, an apparatus, system and method applying folded foil provides a reduced cost process for creating microchannels in comparison with conventional micromachining and skiving. In some embodiments, the folded foil may be applied at any interface, and provides a lower risk to silicon health while allowing for higher throughput integration of microchannels on a silicon die.

In some embodiments, microchannels are created by use of a folded foil copper/metal preform. In some embodiments, a folded foil microchannel preform may implemented at any interface for a cooling solutions, such as: bonding directly on a die backside with no modification of the silicon die (allowing for removal of thermal interface or additional copper in comparison with skived microchannels); implemented within an integrated coldplate (iCP), wherein the folded foil microchannel cooling solution is applied as a 1-TIM solution; or within an enabled coldplate (eCP), wherein the folded foil microchannel cooling solution is used as a 2-TIM solution, with no machining required (thereby simplifying the fabrication of such a cooling structure).

FIGS. 4A to 4D illustrate fabrication of a device utilizing folded foil according to an embodiment.

FIG. 4A: In some embodiments, a folded foil preform 405 is generated. The generation of the folded foil preform may be as illustrated in FIG. 5A and 5B.

FIG. 4B: In some embodiments, the folded foil preform is integrated into a package 400 to create microchannels for fluid coolant flow. As illustrated in FIG. 5B, the fluid coolant flow is provide from the coolant inlet 415 to the coolant outlet 420. A flow control system (not illustrated in FIGS. 4A to 4D) may, for example, be a flow control system 150 as illustrated in FIG. 1.

FIG. 4C: In some embodiments, the microchannels of the folded foil preform may implemented inside an integrated coldplate (iCP) 415 to provide a 1-TIM solution or other similar cooling solution for cooling of the die 425 within the package 400.

FIG. 4D: In some embodiments, the folded foil microchannels may be fabricated under a flow manifold 430 to provide a 0-TIM solution or other similar cooling solution for cooling of the die.

FIGS. 5A and 5B illustrate the formation of folded foil material according to an embodiment.

FIG. 5A: In some embodiments, a foil, such as copper, is folded in one of a plurality of ways. In this illustration, the folding of the foil may include, but is not limited to, a sawtooth pattern; a square pattern 520; or a serpentine pattern 530. Each particular folding pattern may require a different processing to achieve a desired folded foil geometry.

FIG. 5B: In a particular example, a folded foil material 540 may include the illustrated serpentine folded foil, wherein the folding has produced microchannels 545. The folded foil material may vary in, for example, a foil thickness, a pitch between folds; and a height of the folds.

In some embodiments, efficiency of the folded foil microchannels may be modulated via design of the folded foil. Combinations of different design options result in different embodiments of cooling solutions. In some embodiments, in contrast with common conventional process for creating microchannels using skiving (such as illustrated in FIG. 3) a process includes the use of the folded foil to create microchannels 545 for fluid cooling of an electronic device. In operation, the resulting material can provide effective heat transfer coefficients using low or medium flow rates.

In device fabrication, the cost of implementing fluid cooling with folded foil may be significantly lower than with skived microchannels. Skived microchannels are fundamentally a machining process where each unit is skived individually. In some embodiments, folded foil is generated as a large sheet, which may then be clipped or singulated to a desired size and integrated into a 0-TIM, 1-TIM, or 2-TIM design or other similar cooling design using high volume manufacturing techniques.

The amount of folded foil material in a cooling solution may be defined as a length in the fold direction (LFD) 560 and a length in the transverse direction (LTD) 570. In an embodiment of a package, fluid coolant is pumped through the microchannels of the folded foil material in the transverse direction.

In some embodiments, a cooling solution utilizing folded foil may implemented as, for example, an on-die backside installation (0-TIM solution or similar cooling solution); as folded foil MCs in an integrated coldplate (1-TIM solution or similar cooling solution); or as folded foil MCs in an enabled coldplate (2-TIM solution or similar cooling solution) as follows:

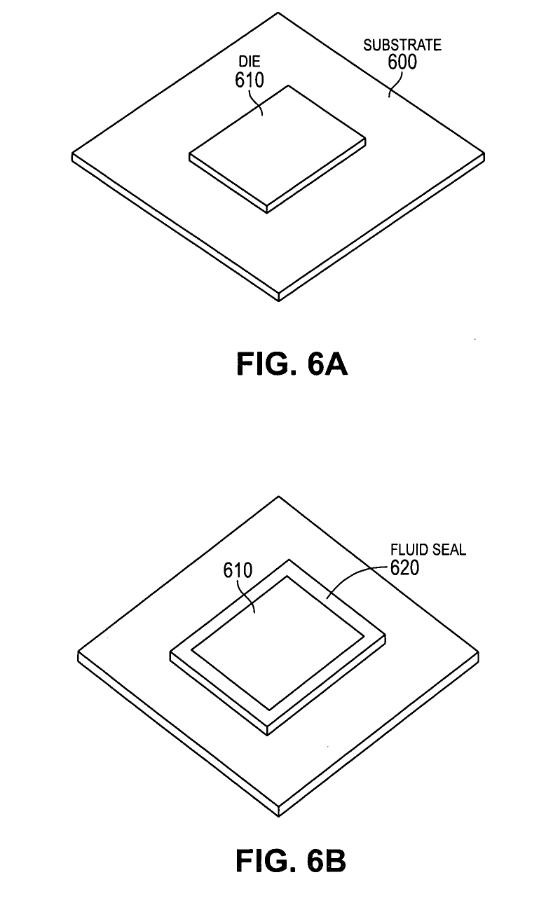

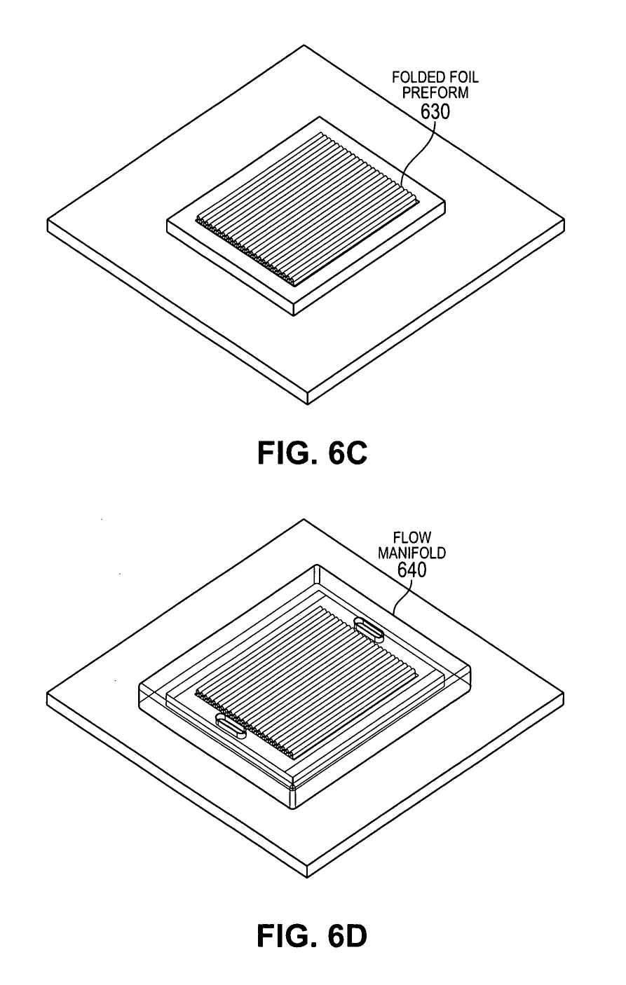

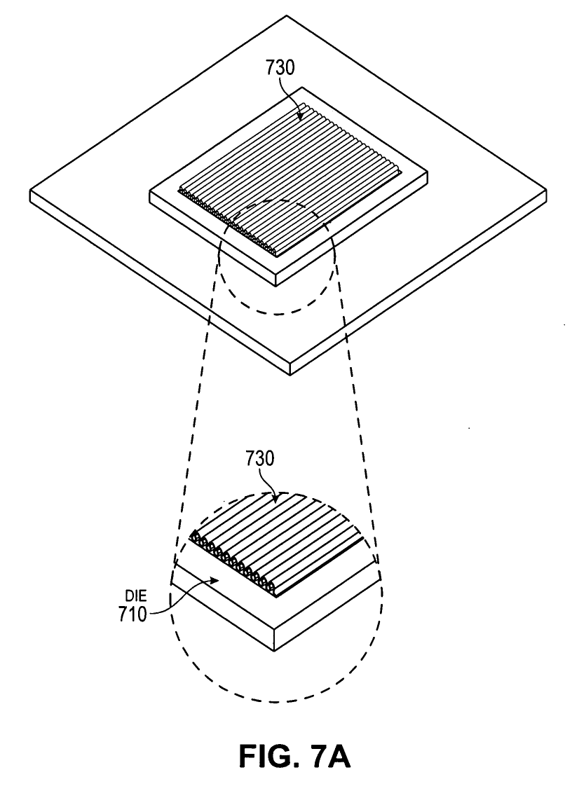

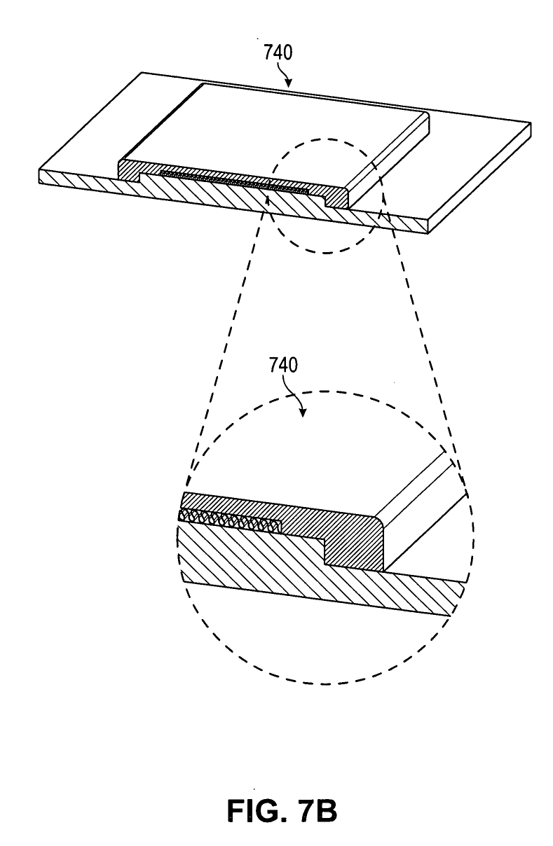

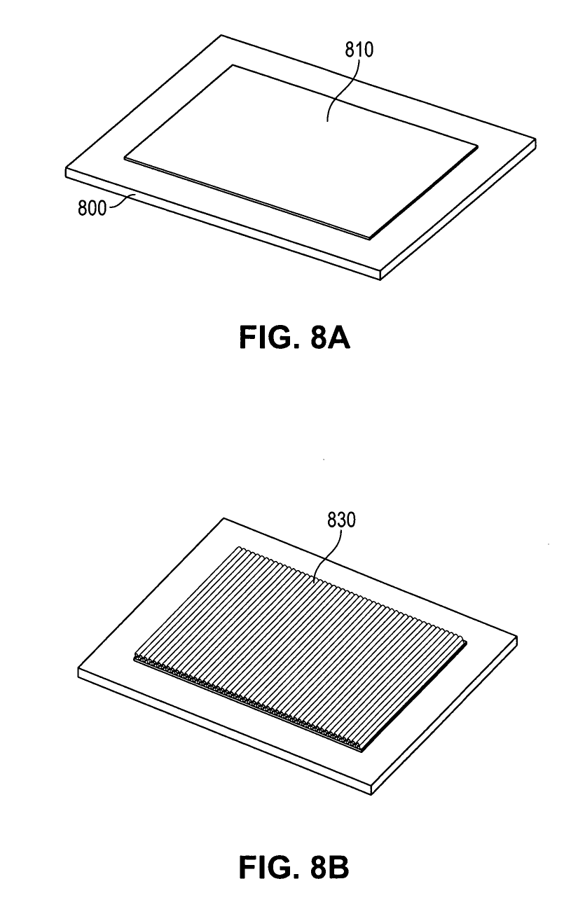

(1) On die backside: Processes for assembly on die backside may be implemented as provided in FIGS. 6A to 6D and FIGS. 7A and 7B. In a particular example, an assembly may be as illustrated for a full thickness die with BSM (backside metallization), but embodiments are not limited to this example.

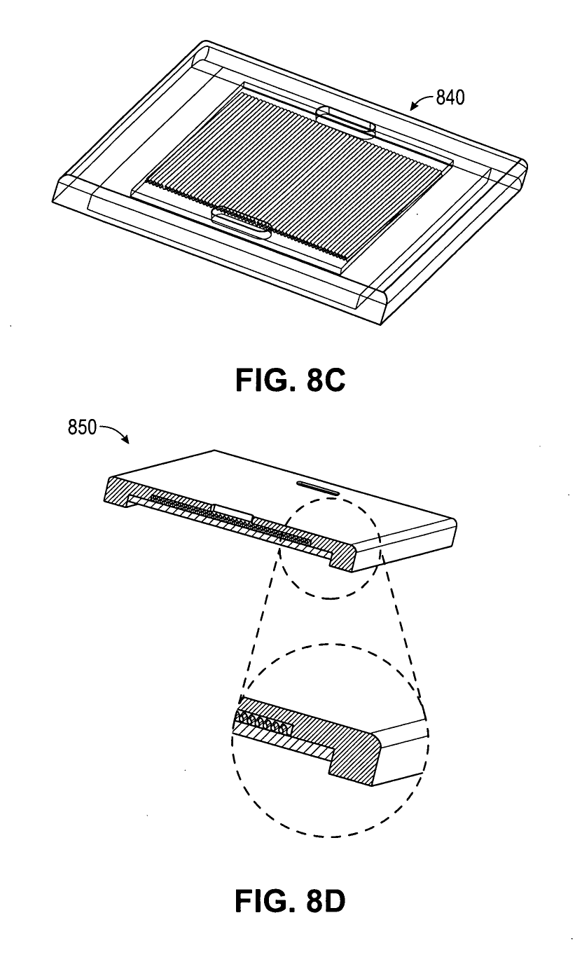

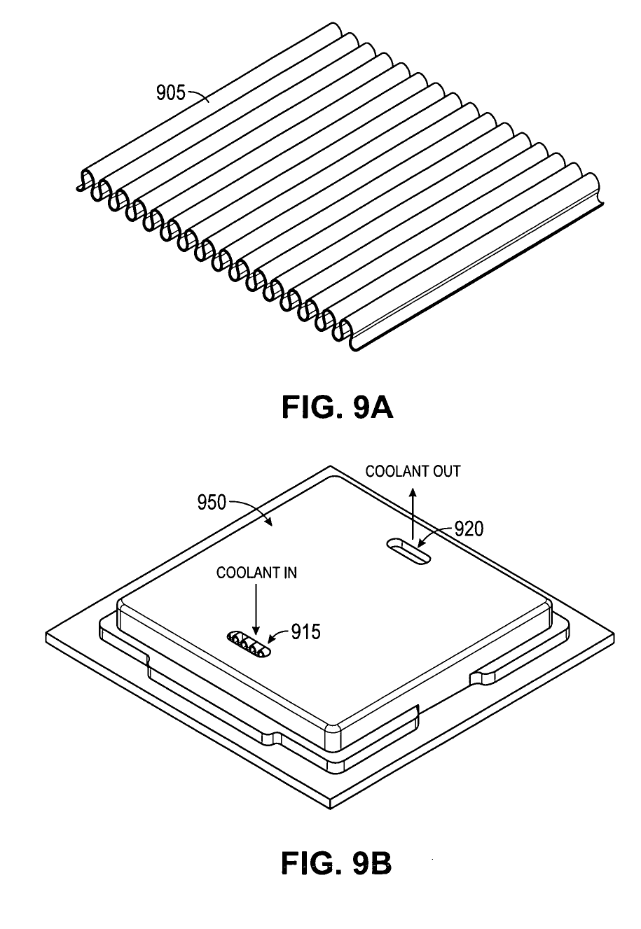

(2) Folded foil MCs in Integrated Coldplate: In some embodiments, an integrated coldplate consists of three key components: A lid (or manifold) with a cavity for a folded foil preform; the folded foil material; and a baseplate that seals the folded foil material into the iCP. In some embodiments, processes for assembly of the iCP may be implemented as provided in FIGS. 8A to 8D. In general, an integrated coldplate is a cooling solution that may replace a conventional integrated heat spreader.

(3) Folded Foil MCs in Enabled Coldplate (2-TIM solution): In some embodiments, a process for integration of folded foil MCs into an eCP is similar to the process illustrated for an iCP in FIGS. 8A to 8D. In some embodiments, a coldplate including a block with a cavity for the folded foil preform, the folded foil material, and a baseplate is assembled. In some embodiments, coldplate is utilized as a 2-TIM cooling solution. In general, an enabled coldplate is a cooling solution that may replace a cooling solution that is on top of a conventional integrated heat spreader.

FIG. 6A to 6D illustrate fabrication of a fluid cooling solution on a die according to an embodiment.

FIG. 6A: In some embodiments, a die 610 is coupled with a substrate 600.

FIG. 6B: A fluid seal 620 is applied around the die 610. The fluid seal 620 acts to prevent leakage of the coolant fluid outside of the intended flow region.

FIG. 6C: A folded foil preform 630 may be bonded to the surface with, for example, high heat flux via high temperature solder, such as a folded foil preform integrated on a thin solder preform on top of the BSM (backside metallization) die. However, embodiments are not limited to any particular method of bonding the folded form preform. In some embodiments, the folded foil preform 630 includes folded foil material as provided in FIGS. 5A and 5B.

FIG. 6D: A flow manifold 640 is assembled on top of the integrated folded foil preform, where the manifold includes a cavity into which the folded foil preform fits snugly. In some embodiments, the manifold cavity is longer along the LTD direction to allow ease of coolant entry and exit and a uniform flow of coolant through the folded foil microchannels.

FIG. 7A and 7B further illustrate elements of a fluid cooling solution for a die according to an embodiment.

FIG. 7A: Folded foil material 730 is integrated on top of a bare die 710, with a close up view of the folded foil 730 on the die 710 being provided.

FIG. 7B: In some embodiments, a manifold 740 is installed on the folded foil preform, the manifold 740 including a cavity for the folded foil preform. FIG. 7B further provides a cutaway view of the manifold 740 installed on the folded foil, with a close up of the folded foil below the manifold being also provided.

FIG. 8A to 8D illustrate fabrication of a fluid cooling solution in an integrated coldplate according to an embodiment.

FIG. 8A: In some embodiments, a thin solder preform 810 is placed on top of a copper baseplate (BP) 810. However, embodiments are not limited to this particular bonding process.

FIG. 8B: A folded foil preform 830 in placed on top of the solder preform.

FIG. 8C: A flow manifold 840 is placed on top of the folded foil, the folded foil baseplate combination being inserted in a cavity in a lid of the flow manifold 840. In some embodiments, a thin solder preform is placed on top of the folded foil and reflowed to couple the components to ensure a strong mechanical join between the folded foil and the flow manifold, FIG. 8C.

FIG. 8D: In some embodiments, the resulting completed folded foil iCP 850 is then ready for integration onto a package.

In some embodiments, because the iCP assembly is completed ahead of integration onto the package, a high temperature solder may be recommended so that no additional reflow occurs within the iCP during iCP attachment onto the package.

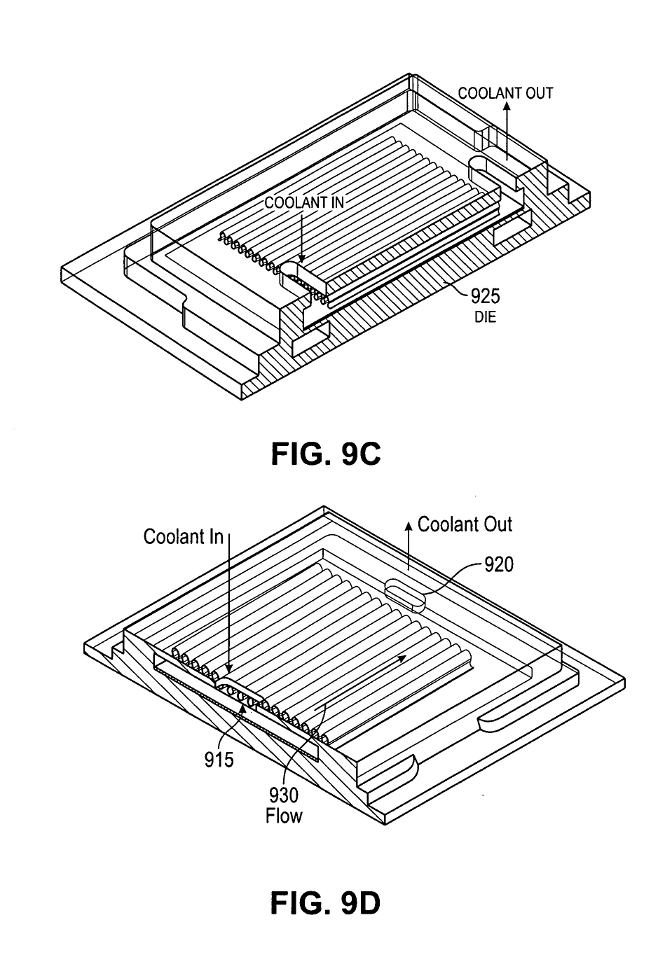

FIGS. 9A to 9D illustrate coolant flows through folded foil microchannels in an integrated coldplate according to an embodiment. FIGS. 9A to 9D illustrate cross-sections of an iCP assembled on a package and the direction of coolant flow.

FIG. 9A: In some embodiments, a folded foil preform 905 is produced, such as illustrated in FIGS. 5A and 5B.

FIG. 9B: The folded foil preform is incorporated into an integrated cooling plate 950, the structure including a coolant inlet 915 and a coolant outlet 920 for the flow of coolant through the microchannels of the folded foil.

FIG. 9C: As illustrated in cutaway view provided in FIG. 9C, the folded foil microchannels allow for coolant flow over the surface of the die 925 to provide an effective solution of removal of heat from the die 925.

FIG. 9D: As illustrated in FIG. 9D, the coolant flow 930 is into the coolant inlet 915, through each of the parallel microchannels, and out of the coolant output 920.

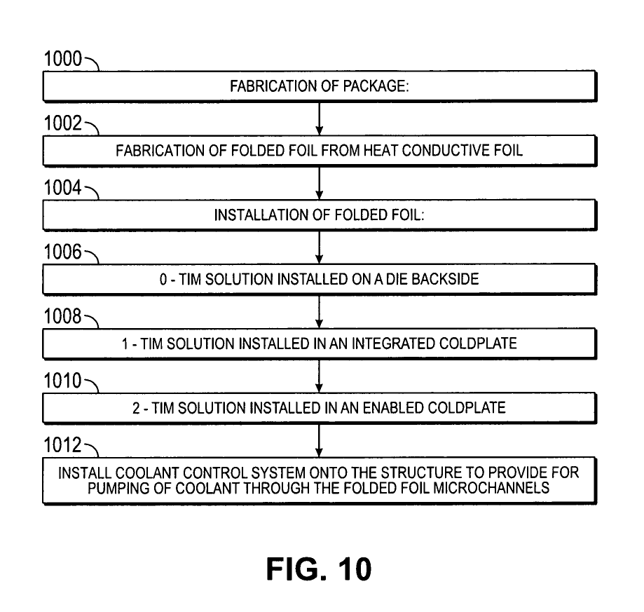

FIG. 10 is a flow chart to illustrate fabrication of a package including folded foil microchannels according to an embodiment. In some embodiments, a process for fabrication of a package 1000 includes, but is not limited to, the following:

1002: Fabricating folded foil from a copper foil or other head conductive foil, the resulting structure including multiple microchannels created by the folding of the material.

1004: Installing the folded foil into a cooling structure, wherein the installation may be in the form of one of the following:

1006: A 0-TIM solution or similar cooling solution installed on a die backside;

1008: A 1-TIM solution or similar cooling solution installed in an integrated coldplate; or

1010: A 2-TIM solution or similar cooling solution installed in an enabled coldplate.

1012: Installing coolant control system onto the cooling solution to provide for the pumping of fluid coolant through the folded foil microchannels in the operation of the resulting package.

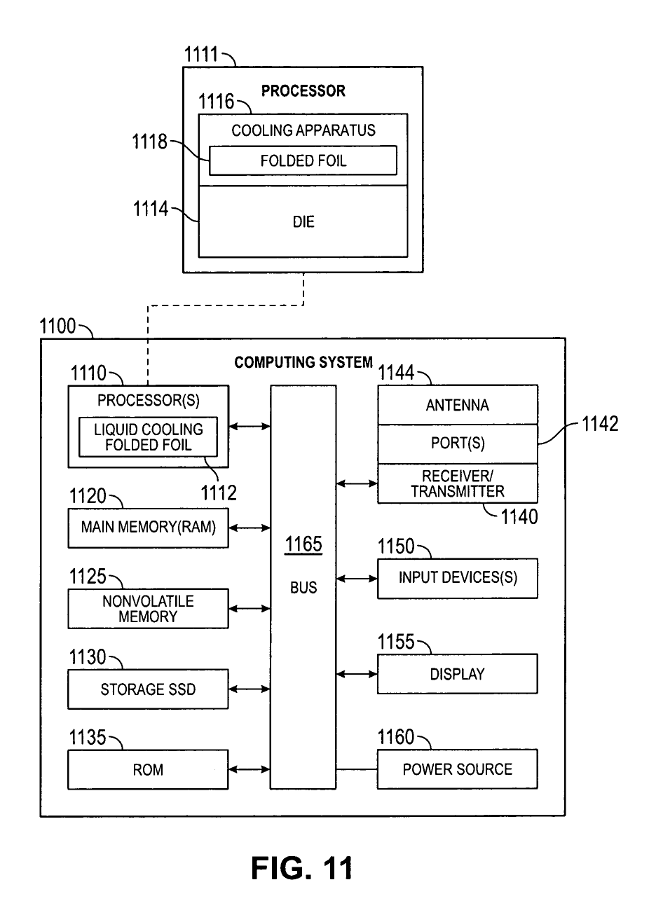

FIG. 11 is an illustration of components of a computing system including a component utilizing fluid cooling through use of folded foil material. Elements shown as separate elements may be combined, including, for example, an SoC (System on Chip) combining multiple elements on a single chip.

In some embodiments, a computing system 1100, which may be, but is not limited to, a computer server, may include one or more processors 1110 coupled to one or more buses or interconnects, shown in general as bus 1165. The processors 1110 may comprise one or more physical processors and one or more logical processors. In some embodiments, the processors may include one or more general-purpose processors or special-processor processors. In some embodiments, the processors include a memory controller.

In some embodiments, one or more of the processors 1110 include a cooling solution utilizing fluid cooling through folded foil microchannels 1112. In some embodiments, a particular processor 1111 includes a cooling apparatus 1116 to provide cooling for at least one die 1114, wherein the cooling apparatus 1116 includes folded foil material 1118. In some embodiments, the cooling apparatus may vary in different implementations, such as a 2-TIM, 1-TIM, or 0-TIM structure or other cooling structure, such as illustrated in FIGS. 2A, 2B, and 2C. In some embodiments, the folded foil material 1118 may be generated as illustrated and described in FIGS. 5A and 5B. In some embodiments, the cooling apparatus 116 may be fabricated as illustrated and described in FIGS. 4A to 4D and FIGS. 6A to 9D

The bus 1165 is a communication means for transmission of data. The bus 1165 is illustrated as a single bus for simplicity, but may represent multiple different interconnects or buses and the component connections to such interconnects or buses may vary. The bus 1165 shown in FIG. 11 is an abstraction that represents any one or more separate physical buses, point-to-point connections, or both connected by appropriate bridges, adapters, or controllers.

In some embodiments, the computing system 1100 further comprises a random access memory (RAM) or other dynamic storage device or element as a main memory 1120 for storing information and instructions to be executed by the processors 1110.

The computing system 1100 also may comprise a non-volatile memory 1125; a storage device such as a solid state drive (SSD) 1130; and a read only memory (ROM) 1135 or other static storage device for storing static information and instructions for the processors 1110.

In some embodiments, the computing system 1100 includes one or more transmitters or receivers 1140 coupled to the bus 1165. In some embodiments, the computing system 1100 may include one or more antennae 1144, such as dipole or monopole antennae, for the transmission and reception of data via wireless communication using a wireless transmitter, receiver, or both, and one or more ports 1142 for the transmission and reception of data via wired communications. Wireless communication includes, but is not limited to, Wi-Fi, Bluetooth™, near field communication, and other wireless communication standards.

In some embodiments, computing system 1100 includes one or more input devices 1150 for the input of data, including hard and soft buttons, a joy stick, a mouse or other pointing device, a keyboard, voice command system, or gesture recognition system.

In some embodiments, the computing system 1100 includes an output display 1155, where the display 1155 may include a liquid crystal display (LCD) or any other display technology, for displaying information or content to a user. In some environments, the display 1155 may include a touch-screen that is also utilized as at least a part of an input device 1150. Output display 1155 may further include audio output, including one or more speakers, audio output jacks, or other audio, and other output to the user.

The computing system 1100 may also comprise power source 1160, which may include a power transformer and related electronics, a battery, a solar cell, a fuel cell, a charged capacitor, near field inductive coupling, or other system or device for providing or generating power in the computing system 1100. The power provided by the power source 1160 may be distributed as required to elements of the computing system 1100.

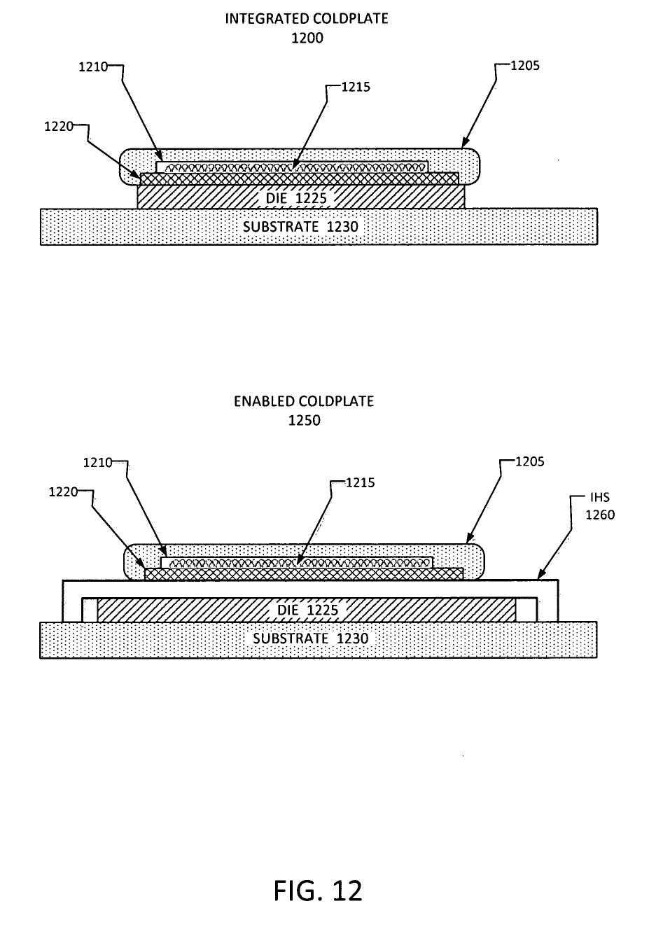

FIG. 12 is an illustration of integrated coldplate and enabled coldplate solutions according to an embodiment. As referred to herein, an integrated coldplate is a cooling solution that may be implemented to replace a conventional IHS (as in a 1-TIM solution), and an enabled coldplate is a cooling solution that may be implemented to replace a cooling solution on top of a conventional IHS (as in a 2-TIM solution).

In a simplified illustration, an integrated coldplate 1200 may include a manifold 1205 including a cavity 1210 to contain a folded foil preform 1215 (shown in an on end view through the microchannels in this illustration); and a baseplate 1220 that operates to seal the folded foil material into the integrated coldplate. In some embodiments, the baseplate 1220 may then be attached to a die 1225 on a package substrate 1230, wherein the attachment of the baseplate 1220 to the die 1225 may include STIM (solder thermal interface material) or PTIM (polymer thermal interface material). While not illustrated here, the integrated coldplate 1200 may include a more complex structure, including, for example, the inclusion of extended feet that attach to the package substrate 1230 through using, for example, IHS sealant material.

An enabled coldplate 1250 may similarly include manifold 1205 including a cavity 1210 to contain a folded foil preform 1215, and a baseplate 1220 that operates to seal the folded foil material into the enabled coldplate. In some embodiments, the baseplate 1220 may then be attached to an integrated heat spreader (IHS) 1260, wherein the IHS 1260 is coupled with the die 1225 on the package substrate 1230. In this instance, the enabled coldplate 1250 is attached to a traditional package with IHS 1260, wherein the attachment to the IHS 1260 may utilize common loading mechanisms such as screws.

In the description above, for the purposes of explanation, numerous specific details are set forth in order to provide a thorough understanding of the described embodiments. It will be apparent, however, to one skilled in the art that embodiments may be practiced without some of these specific details. In other instances, well-known structures and devices are shown in block diagram form. There may be intermediate structure between illustrated components. The components described or illustrated herein may have additional inputs or outputs that are not illustrated or described.

Various embodiments may include various processes. These processes may be performed by hardware components or may be embodied in computer program or machine-executable instructions, which may be used to cause a general-purpose or special-purpose processor or logic circuits programmed with the instructions to perform the processes. Alternatively, the processes may be performed by a combination of hardware and software.

Portions of various embodiments may be provided as a computer program product, which may include a computer-readable medium having stored thereon computer program instructions, which may be used to program a computer (or other electronic devices) for execution by one or more processors to perform a process according to certain embodiments. The computer-readable medium may include, but is not limited to, magnetic disks, optical disks, compact disk read-only memory (CD-ROM), and magneto-optical disks, read-only memory (ROM), random access memory (RAM), erasable programmable read-only memory (EPROM), electrically-erasable programmable read-only memory (EEPROM), magnet or optical cards, flash memory, or other type of computer-readable medium suitable for storing electronic instructions. Moreover, embodiments may also be downloaded as a computer program product, wherein the program may be transferred from a remote computer to a requesting computer.

Many of the methods are described in their most basic form, but processes can be added to or deleted from any of the methods and information can be added or subtracted from any of the described messages without departing from the basic scope of the present embodiments. It will be apparent to those skilled in the art that many further modifications and adaptations can be made. The particular embodiments are not provided to limit the concept but to illustrate it. The scope of the embodiments is not to be determined by the specific examples provided above but only by the claims below.

If it is said that an element “A” is coupled to or with element “B,” element A may be directly coupled to element B or be indirectly coupled through, for example, element C. When the specification or claims state that a component, feature, structure, process, or characteristic A “causes” a component, feature, structure, process, or characteristic B, it means that “A” is at least a partial cause of “B” but that there may also be at least one other component, feature, structure, process, or characteristic that assists in causing “B.” If the specification indicates that a component, feature, structure, process, or characteristic “may”, “might”, or “could” be included, that particular component, feature, structure, process, or characteristic is not required to be included. If the specification or claim refers to “a” or “an” element, this does not mean there is only one of the described elements.

An embodiment is an implementation or example. Reference in the specification to “an embodiment,” “one embodiment,” “some embodiments,” or “other embodiments” means that a particular feature, structure, or characteristic described in connection with the embodiments is included in at least some embodiments, but not necessarily all embodiments. The various appearances of “an embodiment,” “one embodiment,” or “some embodiments” are not necessarily all referring to the same embodiments. It should be appreciated that in the foregoing description of exemplary embodiments, various features are sometimes grouped together in a single embodiment, figure, or description thereof for the purpose of streamlining the disclosure and aiding in the understanding of one or more of the various novel aspects. This method of disclosure, however, is not to be interpreted as reflecting an intention that the claimed embodiments requires more features than are expressly recited in each claim. Rather, as the following claims reflect, novel aspects lie in less than all features of a single foregoing disclosed embodiment. Thus, the claims are hereby expressly incorporated into this description, with each claim standing on its own as a separate embodiment.

In some embodiments, an apparatus includes a semiconductor die; a substrate, the semiconductor die being coupled with the substrate; and a cooling apparatus for the semiconductor die, wherein the cooling apparatus includes: a folded foil thermal, the folded foil forming a plurality of microchannels, and a fluid coolant system to direct a fluid coolant through the microchannels of the folded foil.

In some embodiments, the cooling apparatus includes zero or more heat spreaders and heat planes.

In some embodiments, the folded foil preform is coupled with a backside of the semiconductor die.

In some embodiments, the folded foil preform is coupled with the backside of the semiconductor die using a solder preform.

In some embodiments, the folded foil preform is incorporated in an integrated coldplate, the integrated coldplate being coupled with the semiconductor die.

In some embodiments, the integrated coldplate includes a baseplate, the folded foil preform, and a lid, the lid including a cavity for insertion of the folded foil.

In some embodiments, the folded foil preform is incorporated in an enabled coldplate, the enabled coldplate being coupled with the semiconductor die and with an integrated heat spreader.

In some embodiments, the folded foil preform is formed from folding of a metal foil to generate a pattern. In some embodiments, the microchannels are formed in the folds of the metal foil.

In some embodiments, the semiconductor die is a processor.

In some embodiments, a method includes generating a folded foil preform by folding a foil according to a pattern, the folding of the foil generating a plurality of microchannels; installing the folded foil preform in a cooling structure for a semiconductor die; and installing a flow control system for fluid cooling on the cooling structure, the flow control system to direct a fluid coolant through the microchannels of the folded foil.

In some embodiments, the method further includes comprising coupling the folded foil preform with a backside of the semiconductor die.

In some embodiments, coupling the folded foil preform with a backside of the semiconductor die includes using a solder preform.

In some embodiments, the method further includes incorporating the folded foil preform into an integrated coldplate.

In some embodiments, the method further includes coupling the integrated coldplate with the semiconductor die.

In some embodiments, the integrated coldplate includes a baseplate, the folded foil preform, and a lid, the lid including a cavity for insertion of the folded foil preform.

In some embodiments, the method further includes comprising incorporating the folded foil preform in an enabled coldplate.

In some embodiments, the method further includes coupling the enabled coldplate with the semiconductor die and with an integrated heat spreader.

In some embodiments, a computing system includes one or more processors for the processing of data; a dynamic random access memory for the storage of data for the one or more processors; and a cooling apparatus for at least a first processor of the one or more processors, wherein the cooling apparatus includes folded foil, the folded foil forming a plurality of microchannels, and a fluid coolant system to direct a fluid coolant through the microchannels of the folded foil.

In some embodiments, the folded foil is coupled with a backside of the first processor.

In some embodiments, the folded foil is incorporated in an integrated coldplate, the integrated coldplate being coupled with the first processor

In some embodiments, the folded foil is incorporated in an enabled coldplate, the enabled coldplate being coupled with the semiconductor die and with an integrated heat spreader.

In some embodiments, the folded foil is formed from folding of a metal foil to generate a pattern.

In some embodiments, an apparatus includes a semiconductor die; a substrate, the semiconductor die being coupled with the substrate; and a cooling apparatus for the semiconductor die, wherein the cooling apparatus includes folded foil material, the folded foil forming a plurality of microchannels, and a fluid coolant system to direct a fluid coolant through the microchannels of the folded foil material.

In some embodiments, the folded foil material includes a folded foil preform.

In some embodiments, a method includes fabricating a folded foil preform, the folded foil preform including foil that is folded according to a pattern, the folding of the foil generating a plurality of microchannels; installing the folded foil preform in a cooling structure for a semiconductor die; and installing a flow control system for fluid cooling on the cooling structure, the flow control system to direct a fluid coolant through the microchannels of the folded foil preform.

What is claimed is:

1. An apparatus comprising:
a semiconductor die;
a substrate, the semiconductor die being coupled with the substrate; and
a cooling apparatus for the semiconductor die, wherein the cooling apparatus includes:
a folded foil preform, the folded foil forming a plurality of microchannels, and
a fluid coolant system to direct a fluid coolant through the microchannels of the folded foil.

2. The apparatus of claim 1, wherein the cooling apparatus includes zero or more heat spreaders and heat planes.

3. The apparatus of claim 1, wherein the folded foil preform is coupled with a backside of the semiconductor die.

4. The apparatus of claim 3, wherein the folded foil preform is coupled with the backside of the semiconductor die using a solder preform.

5. The apparatus of claim 1, wherein the folded foil preform is incorporated in an integrated coldplate, the integrated coldplate being coupled with the semiconductor die.

6. The apparatus of claim 5, wherein the integrated coldplate includes a baseplate, the folded foil preform, and a lid, the lid including a cavity for insertion of the folded foil preform.

7. The apparatus of claim 1, wherein the folded foil preform is incorporated in an enabled coldplate, the enabled coldplate being coupled with the semiconductor die and with an integrated heat spreader.

8. The apparatus of claim 1, wherein the folded foil preform is formed from folding of a metal foil to generate a pattern.

9. The apparatus of claim 8, wherein the microchannels are formed in the folds of the metal foil.

10. The apparatus of claim 1, wherein the semiconductor die is a processor.

11. A method comprising:
generating a folded foil preform by folding a foil according to a pattern, the folding of the foil generating a plurality of microchannels;
installing the folded foil preform in a cooling structure for a semiconductor die; and
installing a flow control system for fluid cooling on the cooling structure, the flow control system to direct a fluid coolant through the microchannels of the folded foil.

12. The method of claim 11, further comprising coupling the folded foil preform with a backside of the semiconductor die.

13. The method of claim 12, wherein coupling the folded foil preform with a backside of the semiconductor die includes using a solder preform.

14. The method of claim 11, further comprising incorporating the folded foil preform an integrated coldplate.

15. The method of claim 14, further comprising coupling the integrated coldplate with the semiconductor die.

16. The method of claim 15, wherein the integrated coldplate includes a baseplate, the folded foil preform, and a lid, the lid including a cavity for insertion of the folded foil preform.

17. The method of claim 11, further comprising incorporating the folded foil preform in an enabled coldplate.

18. The method of claim 17, further comprising coupling the enabled coldplate with the semiconductor die and with an integrated heat spreader.

19. A computing system comprising:
one or more processors for the processing of data;
a dynamic random access memory for the storage of data for the one or more processors; and
a cooling apparatus for at least a first processor of the one or more processors, wherein the cooling apparatus includes:
folded foil, the folded foil forming a plurality of microchannels, and
a fluid coolant system to direct a fluid coolant through the microchannels of the folded foil.

20. The computing system of claim 19, wherein folded foil is coupled with a backside of the first processor.

21. The computing system of claim 19, wherein folded foil is incorporated in an integrated coldplate, the integrated coldplate being coupled with the first processor

22. The computing system of claim 19, wherein folded foil is incorporated in an enabled coldplate, the enabled coldplate being coupled with the semiconductor die and with an integrated heat spreader.

23. The computing system of claim 19, wherein the folded foil is formed from folding of a metal foil to generate a pattern.
